(19) United States
(12) Patent Application Publication
(10) Pub. No.: US 2008/0117569 A1
(43) Pub. Date: May 22, 2008

(54) Power-supplying device

(76) Inventor: Jia-Shunn Lee, Taoyuan City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/601,801

(22) Filed: Nov. 20, 2006

(51) Int. Cl. H05K 7/20; G06F 1/18; G06F 1/20

(52) U.S. Cl. 361/678; 361/687; 361/693

(57) ABSTRACT

A power-supplying device includes a casing, a power-supplying unit, and a fan. The casing has a set of exhausting holes. An arrangement hole forms on an upper surface of the casing. The power-supplying unit is received in the casing. The fan corresponds to the arrangement hole and is obliquely disposed in the casing. The power-supplying device draws external hot air into the casing. The fan make the hot air flow in the power-supplying device more smoothly, thereby solving the problem of circulation of hot air in the casing.

### BACKGROUND OF THE INVENTION

1. Field of the Invention

The present invention relates to a power-supplying device, and in particular to a power-supplying device having an inclined fan to improve the circulation of internal hot air.

2. Description of Prior Art

As shown in FIG. 1, a conventional power-supplying device comprises a base 10a, a cover 20a, a power-supplying unit (not shown), and a first fan 30a of a larger size. A front wall 11a of the base 10a has a set of exhausting holes 12a. The cover 20a has an arrangement hole 21a and mounted above the base 10a to form a closed casing 1a. The power-supplying unit is received in the casing 1a and connected to a cable 40a. The cable 40a penetrates through the rear side of the casing 1a.

The first fan 30a is disposed on an inner surface of the cover 20a and located at an upper portion of the casing 1a. The first fan 30a corresponds to the arrangement hole 21a. The hot air outside the power-supplying device can be drawn in by the first fan 30a and exhausted via the set of exhausting holes 12a on the front wall 11a, thereby performing heat dissipation.

However, the above power-supplying device is disposed adjacent to the interior of the rear side of the casing 1a (i.e., adjacent to the cable 40a), so that it easily circulates hot air. Therefore, a portion of air cannot be smoothly exhausted through the casing 1a but rather circulates within the casing 1a, causing the accumulation of hot air and the increasing the temperature.

Therefore, some manufactures provide another set of exhausting holes (not shown) at the rear side of the casing 1a to reduce the circulation of hot air. Alternatively, the interior of the casing 1a is provided with an air-guiding piece (not shown). After the hot air is drawn in via the first fan 30a, the hot air can be directly guided by the air-guiding piece to the set of exhausting holes 12a, thereby reducing the circulation of the hot air. However, in terms of the effect of the above device, there is room for improvement.

With reference to FIG. 2, another conventional power-supplying device is shown. Besides providing a first fan 30a on the upper portion of the casing 1a, it is also provided with a second fan 50a having a smaller size on the front wall 11a. The two fans 30a and 50a are arranged in such a manner that they are vertical to each other. The hot air inside the casing 1a can be exhausted via the second fan 50a. In this way, although the circulation of hot air is reduced, the noise generated by the power-supplying device is adversely increased due to the high rotation speed of the second fan 50a. Therefore, there is still inconvenience in use.

Therefore, in view of the above drawbacks, the inventor proposes the present invention to efficiently overcome the drawbacks of prior art based on his deliberate research and expert experience.

### SUMMARY OF THE INVENTION

The object of the present invention is to provide a power-supplying device.

Via an inclined fan, the hot air flows in the power-supplying device more smoothly, thereby solving the problem of internal circulation of the hot air.

Another object of the present invention is to provide a power-supplying device. It can not only dissipate the heat, but also actively adjusts the inclination angle of the fan, thereby dissipating heat from the system provided with the power-supplying device.

In order to achieve the above objects, the present invention provides a power-supplying device, which comprises a casing having a set of exhausting holes, an upper surface of the casing having an arrangement hole; a power-supplying unit received in the casing; and a fan obliquely disposed in the casing to correspond to the arrangement hole.

The present invention produces the following effects: it is only necessary to use one fan to make hot air smoothly flow into the power-supplying device, thereby improving circulation of hot air. The cost of the present invention is less than conventional devices having two fans, and also the noise thereof is reduced. Furthermore, the inclination angle of the fan can be automatically adjusted to dissipate heat within the system.

In order to offer further understanding the characteristics and technical contents of the present invention, a detailed description thereof will be made with reference to the accompanying drawings. However, it should be understood that the drawings and the description are illustrative and not used to limit the scope of the present invention.

### BRIEF DESCRIPTION OF THE DRAWINGS

FIG. 1 is a perspective view of the conventional power-supplying device;

FIG. 2 is a perspective view of another conventional power-supplying device;

FIG. 3 is a perspective view showing the power-supplying device of the first embodiment of the present invention;

FIG. 4 is an exploded perspective view showing the power-supplying device of the first embodiment of the present invention;

FIG. 5 is a cross-sectional view showing the power-supplying device of the first embodiment of the present invention;

FIG. 6 is a schematic view showing the cover and the fan of the power-supplying device of the second embodiment of the present invention;

FIG. 6A is a partially enlarged view of the portion A of FIG. 6;

FIG. 7 is a cross-sectional view showing the power-supplying device of the second embodiment of the present invention;

FIG. 8 is a perspective view showing the elevating device of the power-supplying device of the second embodiment of the present invention; and

FIG. 9 is an exploded perspective view showing the elevating device of the power-supplying device of the second embodiment of the present invention.

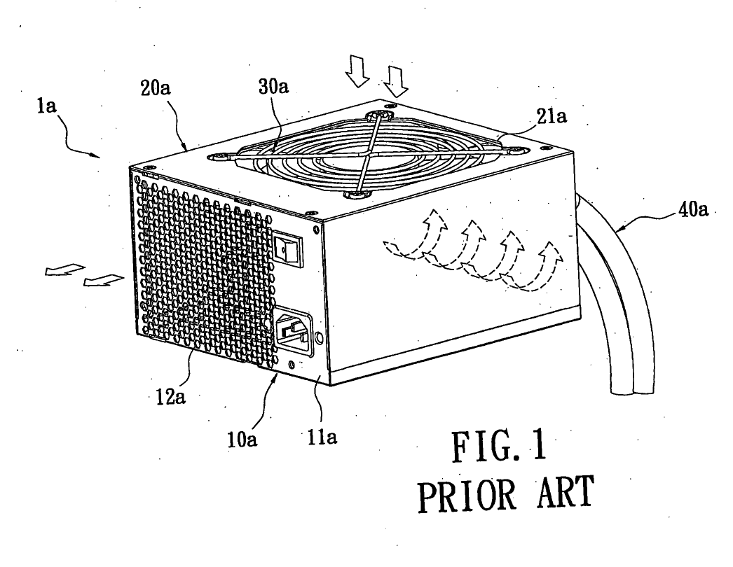

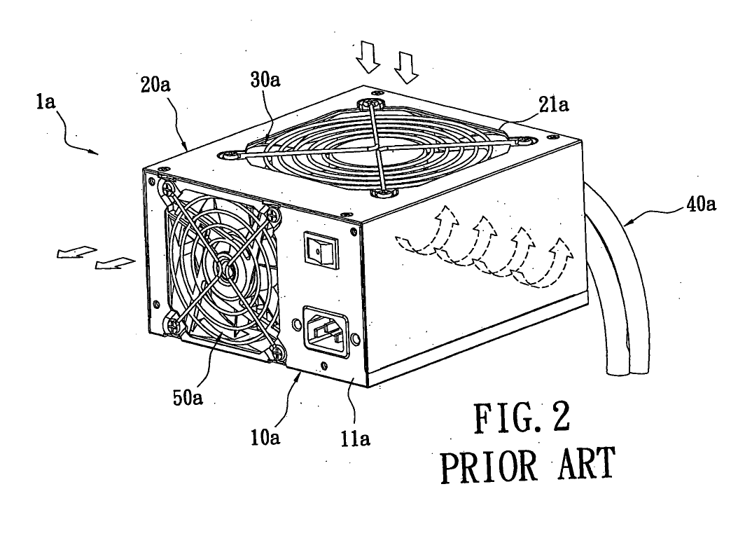

### DETAILED DESCRIPTION OF THE INVENTION

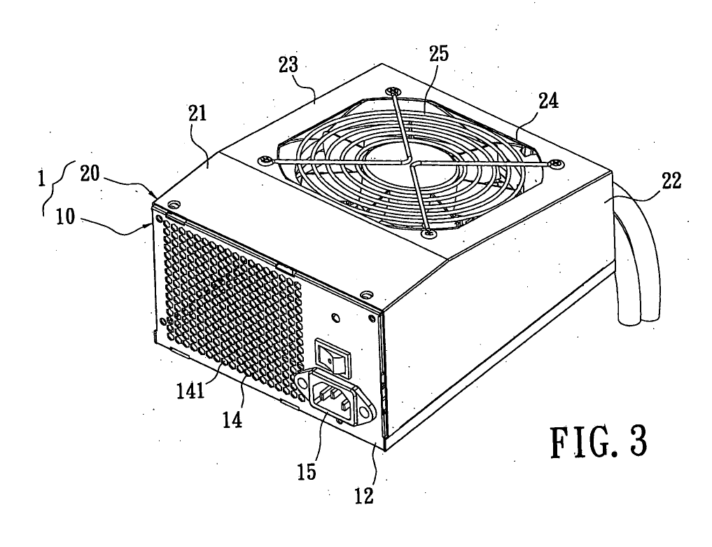

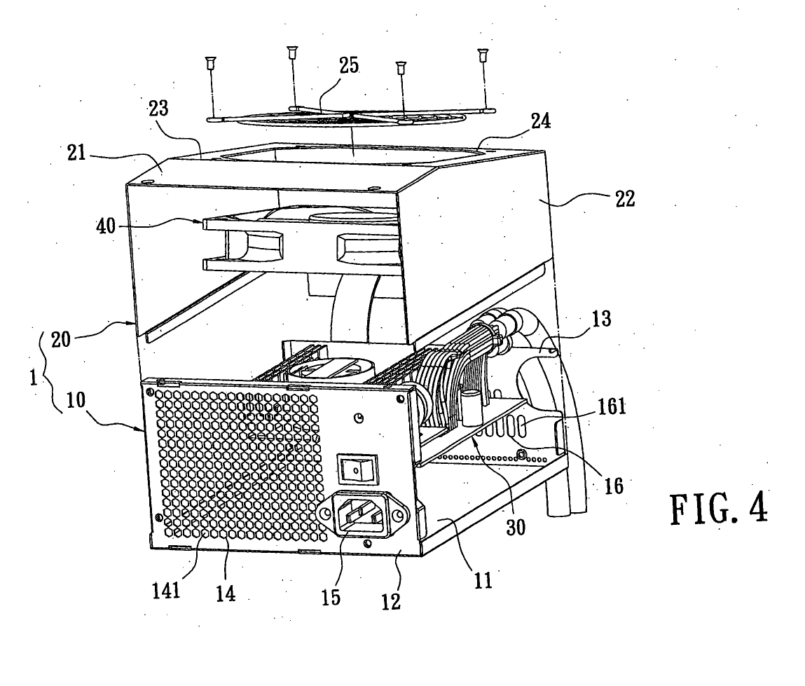

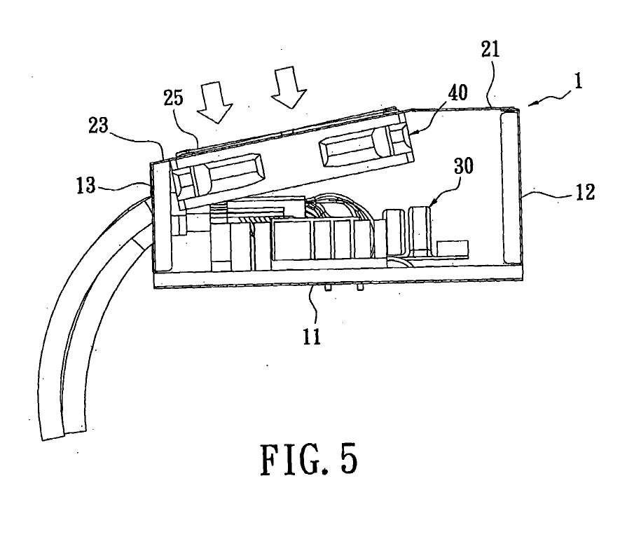

With reference to FIGS. 3 to 5, the drawings show a first embodiment of the present invention. The power-supplying device comprises a casing 1, a power-supplying unit 30, and a fan 40.

The casing 1 is slightly formed into a square body and can be mounted in a system such as a personal computer, an industrial computer, a workstation or a server (not shown). After being connected with to a power socket, it can provide the necessary electricity for the system.

The casing 1 comprises a base 10 and a cover 20. The base 10 has a bottom plate 11, a front wall 12, and a rear wall 13. The front and rear walls 12, 13 are formed by extending upwardly from the front and rear sides of the bottom plate 11. The front wall 12 has a first set of exhausting holes 14 for exhausting hot air. The first set of exhausting holes 14 is formed with a plurality of heat-dissipating holes 141. One side of the first set of exhausting holes 14 has a socket 15 for connecting to power. The rear wall 13 has a second set of exhausting holes 16 formed by arranging a plurality of elongated oval heat-dissipating holes 161.

The cover 20 comprises a top plate 21 and two side plates 22 extending in parallel from both sides of the top plate 21. The top plate 21 is provided with a sloping portion 23 extending downwardly toward the opposite side of the first set of exhausting holes 14. The sloping portion 23 is provided with an arrangement hole 24 penetrating through the cover 20. The cover 20 is mounted on the base 10 and formed into a closed casing 1. Furthermore, the outside of the sloping portion 23 is provided with a protective mask 25 corresponding to the arrangement hole 24. The protective mask 25 can be attached on the outside of the cover 20 by means of screws or locking, thereby protecting the fan 40.

The power-supplying unit 30 is attached on the bottom plate 11 of the base 10 and received in the casing 1. The power-supplying unit 30 is electrically connected to the socket 15. Power is introduced into the power-supplying unit 30 via the socket 15. After reducing the voltage of the power and performing rectification, the power is suitable for the system.

In the present embodiment, the fan 40 is an axial flow fan having a larger size. However, the fan is not limited thereto. The fan 40 is attached on the inner face of the sloping portion 23 of the cover 20 and corresponds to the arrangement hole 24, so that the fan 40 can be obliquely disposed within the casing 1. Therefore, the fan 40 can draw in a larger amount of hot air with lower rotation speed.

When the power-supplying device is activated, the fan 40 is used to draw the outside hot air into the casing 1. Since the fan 40 is arranged obliquely, the hot air can be forced to move toward the front wall 12 of the base 10 and exhausted through the first set of exhausting holes 14 without circulating in the casing 1. Even a small portion of air generates internal circulation, and the air will then be directly exhausted through the second set of exhausting holes 16 on the rear wall 13 of the base 10 without accumulating in the casing 1.

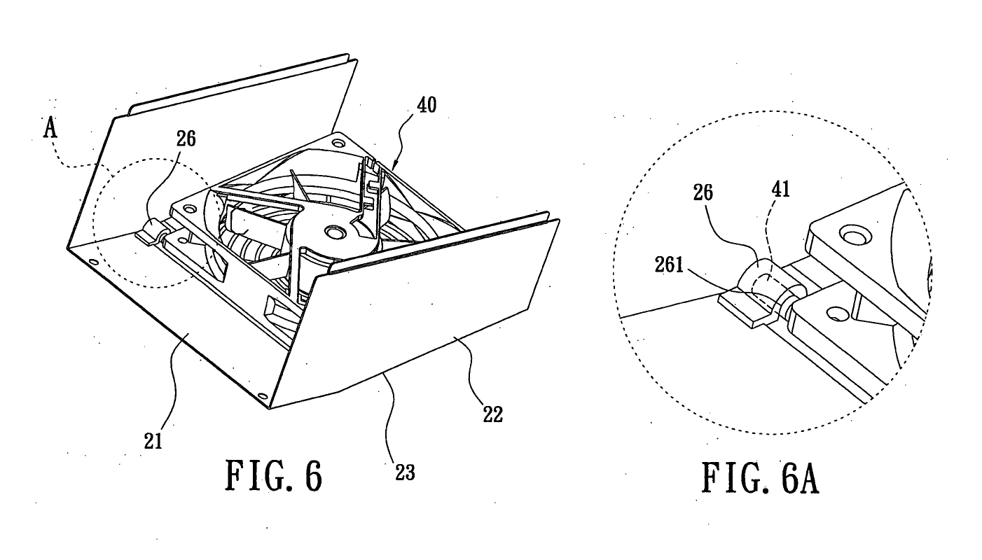

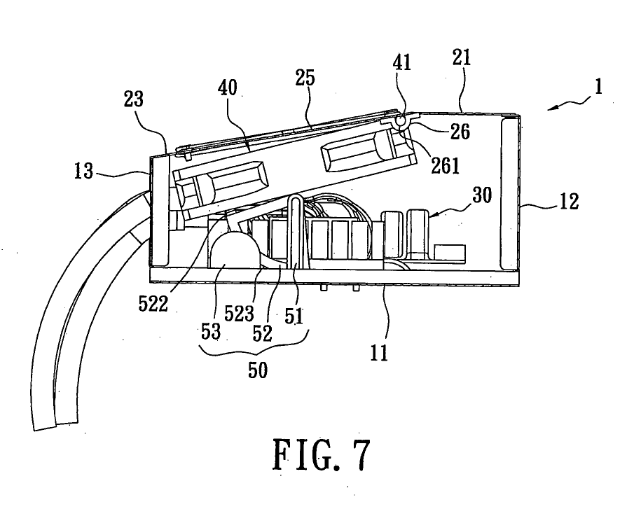

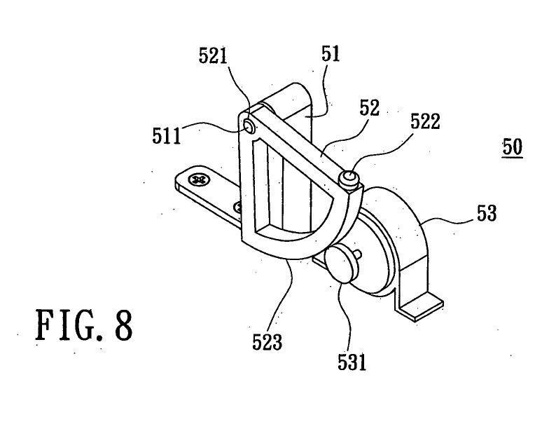

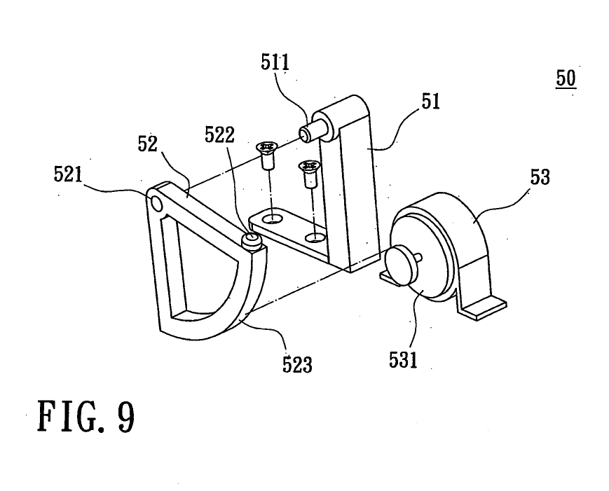

With reference to FIGS. 6 to 9, these drawings show a second embodiment of the power-supplying device of the present invention. The difference between the second embodiment and the first embodiment is described as follows.

Both sides of the inner face of the cover 20 are provided with two spaced pivoting portions 26 to allow the mounting of the fan 40. Each pivoting portion 26 is curved and has a pivoting hole 261.

A cylindrical pivot 41 protrudes outwardly from both sides of the fan 40, respectively. The two pivots 41 correspond to the two pivoting holes 261 and are inserted into the pivoting holes 261. The fan 40 is pivotally connected to the cover 20 via the pivots 41 and the pivoting holes 261 and can rotate with respect to the cover 20.

The power-supplying device can be further provided with an elevating device 50 within the casing 1 to adjust the inclination angle of the fan 40. In the present embodiment, the elevating device 50 is driven by electricity. However, it is not limited thereto and other means such as gas pressure or oil pressure may be used.

The elevating device 50 includes a fixing piece 51, a pushing piece 52, and an electric motor 53. The fixing piece 51 is L-shaped and fixed into the casing 1 by screwing or other means. A cylindrical protruding pillar 511 is disposed on a upper end of the fixing piece 51.

The pushing piece 52 is formed into a sector and has a through hole 521. The protruding pillar 511 of the fixing piece 51 is inserted into the through hole 521 so as to make the pushing piece 52 pivotally connected to the fixing piece 51. The pushing piece 52 is provided with an abutting portion 522 protruding toward the fan 40. The abutting portion 522 is held at the outer edge of the fan 40, so that the pushing piece 52 can cause the fan to move. The bottom end of the pushing piece 52 is further formed with a curved surface 523.

The electric motor 53 is located adjacent to the fixing piece 51 and provided with a rotating portion 531 extending toward the pushing piece 52. The rotating portion 531 abuts against the curved surface 523 of the pushing piece 52. When the rotating portion 531 of the electric motor 53 rotates, the curved surface 523 can generate a relative movement to cause the pushing piece 52 to mate with the electric motor 53 and further cause the fan 40 to change its inclination angle.

The power-supplying device can be also connected to a temperature sensor (not shown). The temperature sensor can be a thermal couple or other detecting element and is disposed within the system or power-supplying device.

The temperature changing within the power-supplying device is detected by the temperature sensor. This activates the elevating device 50 so that the pushing piece 52 can push the fan 40 to rotate, thereby changing the inclination angle of the fan 40 dissipate the heat of a hotter region. Similarly, when the temperature of some members (such as an optical disk drive or a hard disk drive) in the system becomes higher, the temperature change can be also detected by the temperature sensor. Thus, the fan 40 can be allowed to adjust its inclination angle to align with the position of the desired member. The fan 40 draws the hot air generated from the members into the power-supplying device, and finally exhausts the hot air through the first set of exhausting holes 14.

Therefore, in the power-supplying device of the present invention, the fan 40 is obliquely disposed in the casing 1, so that the hot air drawn into the casing 1 can be forced toward the first set of exhausting holes 14. In this way, the hot air can smoothly flow in the casing 1, so that the hot air cannot accumulate in the casing to generate the circulation of air. Instead, the hot air will be directly exhausted through the first set of exhausting holes 14.

Since only one large and low-speed fan 40 is used, the noise is much lower and the cost is less than the prior art. Furthermore, with the cooperation of the elevating device 50, the inclination angle of the fan 40 can be automatically changed. Thus, heat dissipation can be performed at positions of the system or the power-supplying device that require more heat dissipation.

Although the present invention has been described with reference to the foregoing preferred embodiments, it will be understood that the invention is not limited to the details thereof. Various equivalent variations and modifications may occur to those skilled in this art in view of the teachings of the present invention. Thus, all such variations and equivalent modifications are also embraced within the scope of the invention as defined in the appended claims.

What is claimed is:

1. A power-supplying device, comprising:
a casing having a set of exhausting holes and an arrangement hole formed on an upper surface thereof;
a power-supplying unit received in the casing; and
a fan obliquely disposed in the casing and corresponding to the arrangement hole.

2. The power-supplying device according to claim 1, wherein the casing is mounted in a personal computer, an industrial computer, a workstation, or a server.

3. The power-supplying device according to claim 1, wherein the casing comprises a base and a cover mounted on the base, the base has a front wall, the set of exhausting holes form at the front wall, and the arrangement hole penetrates through the cover.

4. The power-supplying device according to claim 3, wherein the base has a rear wall opposite to the front wall, and the rear wall further has another set of exhausting holes.

5. The power-supplying device according to claim 3, wherein the cover is further provided with a protective mask, and the protective mask is screwed to the outside of the cover to correspond to the arrangement hole.

6. The power-supplying device according to claim 3, wherein the cover has a sloping portion extending downwardly toward the opposite side of the set of exhausting holes, the arrangement hole is located on the sloping portion, and the fan is attached on an inner surface of the sloping portion.

7. A power-supplying device, comprising:
a casing having an set of exhausting holes, and an arrangement hole formed on an upper surface thereof;
a power-supplying unit received in the casing;
a fan obliquely disposed in the casing to correspond to the arrangement hole; and
an elevating device disposed in the casing for adjusting the inclination angle of the fan.

8. The power-supplying device according to claim 7, wherein the casing is mounted in a personal computer, an industrial computer, a workstation, or a server.

9. The power-supplying device according to claim 7, wherein the casing comprises a base and a cover mounted on the base, the base has a front wall, the set of exhausting holes form at the front wall, and the arrangement hole penetrates through the cover.

10. The power-supplying device according to claim 7, wherein the elevating device is provided with a pushing piece, the pushing piece is provided with an abutting portion protruding toward the fan, the abutting portion is held at the outer edge of the fan, and the pushing piece is used to adjust the inclination angle of the fan.

11. The power-supplying device according to claim 10, wherein the elevating device further comprises a fixing piece and an electric motor, the fixing piece is attached in the casing, the electric motor is disposed adjacent to the fixing piece, and the pushing piece is pivotally connected to the fixing piece to mate with the electric motor.

12. The power-supplying device according to claim 11, wherein the fixing piece has a protruding pillar, the pushing piece has a through hole, and the protruding pillar is inserted into the through hole.

13. The power-supplying device according to claim 11, wherein the electric motor has a rotating portion to extend toward the pushing piece, the pushing piece forms a curved surface, and the rotating portion abuts against the curved surface.

14. The power-supplying device according to claim 9, wherein the base has a rear wall opposite to the front wall, and the rear wall has another set of exhausting holes.

15. The power-supplying device according to claim 9, wherein the cover is further provided with a protective mask, and the protective mask is screwed to the outside of the cover to correspond to the arrangement hole.

16. The power-supplying device according to claim 9, wherein the cover has two pivoting holes, two pivots are disposed on the fan and corresponding to the pivoting holes, the pivot is inserted into the pivoting hole, and the fan is pivotally connected to the cover via the pivots and the pivoting holes.

17. The power-supplying device according to claim 9, wherein the cover has a sloping portion extending downwardly toward the opposite side of the set of exhausting holes, and the arrangement hole is located on the sloping portion.
